(19) United States
(12) Patent Application Publication
(10) Pub. No.: US 2008/0226843 A1
(43) Pub. Date: Sep. 18, 2008

(54) Laser Cladding on Low Heat Resistant Substrates

(76) Inventors: Harold Haruhisa Fukubayashi, Mito-shi (JP); Roland C. Gassmann, New Castle, PA (US)

Correspondence Address: PRAXAIR, INC.;LAW DEPARTMENT - M1 557, 39 OLD RIDGEBURY ROAD, DANBURY, CT, 06810-5113, US

(21) Appl. No.: 11/993,736

(22) PCT Filed: Jun. 20, 2006
(86) PCT No.: PCT/US2006/023877

§ 371 Date: May 21, 2008

Related U.S. Application Data
(60) Provisional application No. 60/691,801, filed on Jun. 20, 2005.

(51) Int. Cl. C23C 24/10; B23K 26/34; C22C 19/07; C22C 19/03; C22C 19/05; C22C 32/00; C23C 14/28

(52) U.S. Cl. 427/597; 219/121.66; 419/10; 420/441; 420/435

(57) ABSTRACT

This invention relates to laser cladding of components used in high temperature-corrosive applications, such as those associated with metallurgical vessels' lances, nozzles and tuyeres, for extending their service life under such severe conditions. In particular, this invention relates to a method for applying a high melting point material onto a substrate, said substrate having a melting point temperature below the melting point temperature of the high melting point material, comprising: (a) moving a laser beam generated from a laser over the surface of said substrate, said laser beam comprised of wavelengths from about 300 to about 10,600 nanometers; (h) providing a metal, alloy, or metal-alloy composite powder to the surface of said substrate; and (c) generating sufficient power to the laser to superficially heat said substrate and to effect a fusion bond between the metal, alloy or metal-alloy composite powder and the surface of said substrate.

### FIELD OF THE INVENTION

The invention relates to a method of laser cladding high melting point metals, alloys and/or metal composites onto low heat resistant substrates, such as copper or similar materials. In particular, the invention relates to laser cladding of components used in high temperature-corrosive applications, such as those associated with metallurgical vessels' lances, nozzles and tuyeres, for extending their service life under such severe conditions.

### BACKGROUND OF THE INVENTION

Tuyeres, often mounted on a bustle pipe inject air, oxygen and fuel into blast furnaces and smelters, such as Pierce-Smith converters. Similar to tuyeres, gas injection nozzles inject oxygen and fuel into electric arc furnaces' bath of molten steel. In addition, lance nozzles inject oxygen and fuel into basic oxygen furnaces used to manufacture steel. These lances, nozzles and tuyeres are usually water-cooled and made of high conductivity copper or copper-base alloys that have minimal resistance to molten slag or metal attack. In addition to these, metallurgical vessels' lances and nozzles typically experience both hot particle erosion and molten slag or metal attack.

An additional problem is the presence of corrosive gases. These corrosive gases include acids and non-acidic reactive metal vapors. The corrosive gases, such as chlorine and sulfur dioxide often originate from fuels or the oxidation of metal sulfides in the feed stock or melt. Similar to acidic gases, reactive vapors such as, cadmium, lead, zinc, etc. typically originate from their inclusion in scrap steel feed to blast and electric arc furnaces. These gases aggressively attack metal injection devices. For example, sulfur dioxide readily reacts with copper and forms sulfides such as, copper sulfide (CuS).

Yet another problem with coated tuyeres and nozzle tips is cracking after a period of service under extreme cyclic heating and cooling. This cracking can propagate toward the inner wall, causing eventual water leakage.

To remedy these problems, various claddings or coatings on components have been tried by the industry. To clad the components, the industry commonly uses either solid ceramic, hard alloy, or hard surface overlay on soft alloy substrate. The overlay can be done by a welding, a spray-fuse process, or a transferred plasma arc (PTA). The overlay materials are either various Co alloys (e.g., Satellite) or spray-fuse Co—Cr—B—Si, Ni—B—Si, or Ni—Cr—B—Si alloys with or without carbide additions. Unfortunately, all these materials wear extensively within a short time and often require as frequent as weekly replacement.

The spray-fuse process employs Ni or Co base alloys with or without carbide particles. Both alloys contain boron (B) and silicon (Si) as fluxing agents to provide wetting action on the substrate when they are fused; however, little or no fusion of the substrate occurs. The overlay often cracks and separates in service due to molten metal attack. Cobalt alloy overlay, regardless of the mode of application, doesn't have strong resistance to wear by dross (dross is extremely hard micron-size intermetallic compound suspended in molten zinc or zinc alloy) or attack by zinc. The most widely used type of spray-fuse coating is a coating of nickel based alloys. The coating typically is relatively thick, as much as 0.125″. With a reduced thickness of 0.010 to 0.020″, the coating is lost very rapidly due to the extremely high surface loading coupled with wedging of fine hard dross (iron-zinc-aluminum intermetallic), and the coating provides no significant economic gains. On the other hand, the thick spray-fuse coatings crack, which leads to interface attack by zinc or aluminum. Thus, the coating eventually spalls before actually losing the coating through wear.

The PTA process essentially is just a welding process using powder feed and plasma energy rather than conventional stick or submerged arc welding. With PTA weld overlay of cobalt alloys, dilution, while less than the arc welding, still is excessive.

A recent development in protective coating is the use of thermal spray coatings. U.S. Pat. No. 6,503,442 discloses coated devices for use with corrosive environments at high temperatures. The device has a bond coat consisting of 0 to 5 weight percent carbon, 20 to 40 weight percent chromium, 0 to 5 weight percent nickel, 0 to 5 weight percent iron, 2 to 25 weight percent total molybdenum plus tungsten, 0 to 3 weight percent silicon, 0 to 3 weight percent boron, and the balance cobalt and essential impurities to provide sulfidation resistance at high temperatures. A zirconia-base ceramic coating may cover the bond coat for heat resistance and a boride or carbide coating may cover the zirconia for additional resistance to corrosion.

There is a continuing need for protecting components used in modem high temperature-corrosive applications, such as those associated with metallurgical vessels' lances, nozzles and tuyeres, in order to extend their service life under such severe conditions. Namely, an overlaying method is needed that does not result in significant damage to the component surface, especially those components having low heat resistance. The present invention addresses this need.

### SUMMARY OF THE INVENTION

This invention relates to a method for applying a high melting point material onto a substrate, said substrate having a melting point temperature below the melting point temperature of the high melting point material, comprising:

(a) moving a laser beam generated from a laser over the surface of said substrate, said laser beam comprised of wavelengths from about 300 to about 10,600 nanometers;

(b) providing a metal, alloy or metal-alloy composite powder to the surface of said substrate; and

(c) generating sufficient power to the laser to superficially heat said substrate and to effect a fusion bond between the metal, alloy or metal-alloy composite powder and the surface of said substrate. The laser creates superficial heating of said substrate without distortion of said substrate. The substrate is preferably copper or a copper-base alloy.

This invention also relates to a method of forming a machine component for use with corrosive environments at high temperatures comprising applying a high melting point material onto the surface of a substrate having a contour of the desired shape of the machine component, said substrate having a melting point temperature below the melting point temperature of the high melting point material, by laser cladding the surface of said substrate to form a laser clad layer, said laser cladding comprising:

(a) moving a laser beam generated from a laser over the surface of said substrate, said laser beam comprised of wavelengths from about 300 to about 10,600 nanometers;

(b) providing a metal, alloy or metal-alloy composite powder to the surface of the substrate; and

(c) generating sufficient power to the laser to superficially heat said substrate and to effect a fusion bond between the metal, alloy or metal-alloy composite powder and the surface of the substrate. The laser creates superficial heating of said substrate without distortion of said substrate, so as to provide the laser clad layer having the contour as the design shape of said machine component. The substrate is preferably copper or a copper-base alloy.

This invention further relates to a machine component for use with corrosive environments at high temperatures comprising:

(a) a low melting point substrate having a contour of the desired shape of said machine component; and

(b) a laser clad layer comprising a high melting point metal, alloy or metal-alloy composite covering the surface of said substrate;

wherein said substrate has a melting point temperature below the melting point temperature of the high melting point metal, alloy or metal-alloy composite covering the surface of said substrate. The laser clad layer has the contour as the design shape of said substrate, said laser clad layer applied by a laser generating a laser beam comprised of wavelengths from about 300 to about 10,600 nanometers, said laser beam superficially heating said substrate without distortion of said substrate. The machine component can include tuyeres in a blast furnace, lance tips in a basic oxygen furnace, nozzles in an electric arc furnace, and mold plates in continuous slab casters. The machine component is made preferably of copper or a copper-base alloy.

This invention yet further relates to a method for applying a high melting point material onto a substrate, said substrate having a melting point temperature below the melting point temperature of the high melting point material, comprising:

(a) generating a laser beam with a laser, said laser beam comprised of wavelengths from about 300 to about 10,600 nanometers;

(b) discharging a metal, alloy or metal-alloy composite powder onto the surface of said substrate through a powder discharge nozzle with an axial alignment different from the axial alignment of the laser, and

(c) moving said laser and said powder discharge nozzle across the surface of said substrate to superficially heat said substrate, thereby fusing at least one laser clad layer of a metal, alloy or metal-alloy composite powder to the surface of said substrate. The laser creates superficial heating of said substrate without distortion of said substrate. The substrate is preferably copper or a copper-base alloy.

This invention also relates to a method for applying a high melting point material onto a substrate, said substrate having a melting point temperature below the melting point temperature of the high melting point material, comprising:

(a) generating a laser beam with a laser, said laser beam comprised of wavelengths from about 300 to about 10,600 nanometers;

(b) discharging a metal, alloy or metal-alloy composite powder onto the surface of said substrate through a powder discharge nozzle with an axial alignment different from the axial alignment of the laser;

(c) moving said laser and said powder discharge nozzle across the surface of a first area of said substrate to superficially heat the first area of said substrate, thereby fusing at least one laser clad layer of a metal, alloy or metal-alloy composite powder to the surface of the first area of said substrate;

(d) allowing the first area to cool and then moving said laser and said powder discharge nozzle across the surface of a second area of said substrate to superficially heat the second area of said substrate, thereby fusing at least one laser clad layer of a metal, alloy or metal-alloy composite powder to the surface of the second area of said substrate; and

(e) allowing said second area to cool and then repeating the steps of laser cladding and cooling for additional areas until a total desired area has been laser clad layered. The laser creates superficial heating of said substrate without distortion of said substrate. The substrate is preferably copper or a copper-base alloy.

According to this invention, a high melting point metal, alloy or metal-alloy composite powder overlay for use on a low heat resistant substrate such as tuyeres in a blast furnace, lance tips in a basic oxygen furnace, nozzles in an electric arc furnace, and mold plates in continuous slab casters, is provided by laser techniques that employ a laser beam comprised of wavelengths from about 300 to about 10,600 nanometers. The laser creates superficial heating of said substrate without distortion of said substrate. As used herein, “without distortion” means that the substrate or mechanical component distorts by less than 0.01 inch. It is understood that the steps of the methods described herein can be performed in the order presented or in any other order sufficient to carry out the methods of this invention.

### BRIEF DESCRIPTION OF THE DRAWINGS

FIG. 1 is a Nd:YAG laser clad surface of a CoCrC coating applied onto a copper plate.

FIG. 2 is a Nd:YAG laser clad and polished surface of a CoCrC coating applied onto a copper plate.

### DETAILED DESCRIPTION OF THE INVENTION

The type of laser useful in this invention can vary widely and depends solely on the laser beam wavelength. The absorptivity of a material such as copper or copper-base alloy is a function of the laser beam wavelength. Optical lasers range from ultra violet all the way to infrared, depending on their lasing medium. The absorptivity of copper goes up as the wavelength decreases, which means lasers that generate a short wavelength beam are more suitable than infrared beams in the practice of this invention. As used herein, “absorptivity” means the ratio of radiant energy absorbed by a substrate to that incident upon it.

CO₂ lasers run at 10,600 nanometers, which is high infrared. The Nd:YAG laser runs at 1060 nanometers, which is still infrared. However, the absorptivity of copper is greatly higher at 1060 nanometers than at 10,600 nanometers. Other suitable lasers useful in this invention include, for example, laser diodes and YAG lasers that run between 700 and 1060 nanometers.

The YAG lasers useful in this invention refer to a yttrium-aluminum-garnet lasers. Such lasers also may include a doping material, such as neodymium (Nd), and such a laser is sometimes referred to as an Nd:YAG laser. This invention may also be practiced with YAG lasers that use other dopant materials. The YAG laser system useful in practicing this invention is commercially available. When operated in continuous wave mode the laser provides sufficient heat at a specific spot to effect superficial heating of the substrate surface and cladding of the metal, alloy or metal-alloy composite powder.

The material-wavelength-absorptivity correlation is important in the practice of this invention. Particularly, wavelengths at and below 1060 nanometers are preferred. Ultra violet lasers may be useful in carrying out this invention, but there are no continuous wave lasers available that produce a sufficiently powerful beam for this application. What can work in the practice of this invention are multi-kilowatt lasers that generate laser beams ranging from about 300 to about 10,600 nanometers, preferably about 1060 nanometers or less, and more preferably from about 700 to about 1060 nanometers.

The lasers useful in this invention are not limited to continuous wave beams since this invention is directed more to pulse frequency versus heat conductivity. Laser beams of wavelengths from about 300 to about 10,600 nanometers, preferably 1060 nanometers or less, are preferably delivered via fiber optics.

Laser cladding provides unique methods for applying metallurgically bonded coatings to virtually any size and configuration of workpiece. As an illustration, a laser beam can be directed from a laser generator to a selected work cell through a system of enclosed laser beam ducts using optically polished, water-cooled mirrors. The laser beam is then focused to a spot of high power density using the appropriate optics attached to a tooling end-effector and the focused beam is translated over the workpiece surface to rapidly melt and solidify the cladding metal, alloy or metal-alloy composite powder. The delivered laser power and focal spot diameter can be varied to produce power densities on the workpiece surface capable of superficially heating the surface.

Precise control of laser energy permits accurate deposition of coating thicknesses ranging from 0.0001 to 0.080 inches in a single pass. The laser clad coatings are impervious overlays metallurgically bonded to the substrate, and dilution caused by intermixing of the coating metal, alloy or metal-alloy composite powder and the substrate is routinely controlled at less than 5%. Due to the low heat input of the laser cladding process and superficial heating of the workpiece surface, coated components exhibit minimal distortion, and metallurgical changes in the substrate are negligible. The method of this invention uses a laser that generates a laser beam comprised of wavelengths from about 300 to about 10,600 nanometers, to create superficial heating that does not create weld-induced damage or cracking to the substrate surface.

The lasers utilized in the practice of this invention are known in the art. As an illustration, the laser generates a laser beam that is used in the cladding operation. In a typical manner, the laser is directed through a beam guide including fiber optic materials, through a mirror, and through a focus lens. The laser then impinges on the work piece. Components such as beam guide, mirror, and focus lens are items known in the art of laser cladding. Powder of a metal, alloy or metal-alloy composite may be provided by a powder feeder. The powder can be fed onto the workpiece through powder feed nozzle. Other typical components of the laser system may include a video camera and video monitor. The workpiece is typically held on a work table.

The cladding system may also employ a controller or a computer numerically controlled positioning system. The controller can coordinate components of the system. As is known in the art, the controller may also include a digital imaging system. The controller guides movement of the laser and powder feed across the face of the workpiece. In an embodiment, movement of the workpiece in the XY plane can be achieved through movement of the worktable. Movement in the up and down, or Z-direction can be achieved by control of the laser arm; i.e., pulling it up or lowering it. Alternative methods of control may be possible, such as controlled movement of the workpiece in all three directions, X, Y, and Z.

Through use of the controller, the laser may be guided across a face of the workpiece in a selected pattern of movement. The laser can trace a stitch pattern along the face of the workpiece. The spacing between the stitches can be within the range of about 0.020 inches to about 0.028 inches. Preferably, successive stitches are spaced such that there is no appreciable or minimal non-fused area between the stitches. Furthermore, the movement of the laser in turning corners can be a gradual or curved movement such that an over buildup of fused material can be avoided when moving from a stitch in one direction to another direction. Other laser stitching techniques are known in the art and may be applied to the method of this invention.

The laser system useful in this invention may preferably contain a powder feeder to deposit powdered metal through a nozzle discharge. In a preferred embodiment, the laser cladding system uses an off-axial arrangement for the powdered nozzle; i.e., the axis of discharge for powder nozzle is different from the axis alignment of the laser itself. The preferred rate of powder discharge is in the range of about 0.01 to 0.10 grams per second. The discharge of metal powder can be a further part of the controller.

The powder discharged in the laser cladding system may be a metal, alloy or metal-alloy composite powder. The powder used in the laser cladding process should be compatible with the substrate illustrative metal, alloy or metal-alloy composite powders useful in this invention include cobalt-based superalloys and nickel-based superalloys. Preferred metal, alloy or metal-alloy composite powders include cobalt-chromium-carbide and nickel-chromium-aluminum. The dimensions of the powder preferably range from about 100 to 300, preferably from about 120 to 270, as measured by mesh size of the powder. The metal, alloy or metal-alloy composite may or may not be blended with particles of hard intermetallic compounds, such as tungsten carbide and chromium carbide.

Cladding materials useful in this invention can be either metal, alloy or metal-alloy composites consisting of ceramics and intermetallic, carbide, boride, nitride, etc. The added amounts of the ceramics and intermetallic can be between 2 to 80% depending on the specific application and requirements. The particle size of the added compound in metals and alloys can be varied depending on the amount of dissolution desired. Use a larger particles for less dissolution and smaller particles for more dissolution.

A preferred metal, alloy or metal-alloy composite powder used to form the laser clad layer comprises, by weight percent, about 5 to 20 carbon, about 20 to 40 chromium, about 0 to 5 nickel, about 0 to 5 iron, about 0 to 25 molybdenum, about 0 to 25 tungsten, about 0 to 3 silicon, about 0 to 3 boron, and balance cobalt. The cobalt-base alloys of the invention advantageously contain, by weight percent, about 20 to 40 percent chromium, unless specifically expressed otherwise, all compositions provided in this specification are expressed in weight percent. The chromium provides oxidation resistance and some additional resistance to oxidation for the cobalt matrix.

A total addition of about 3 to 20 molybdenum and tungsten may enhance the alloy's sulfidation resistance. This is particularly important for protecting copper and copper-base alloy devices used in high temperature-corrosive applications, such as those associated with metallurgical vessels' lances, nozzles and tuyeres. At the high temperatures generated with smelting and processing, copper injection devices quickly react with sulfur dioxide to form detrimental CuS. The change in density associated with the sulfidation often causes ceramic coatings to spall off. In addition, ceramic coatings generally tend to have porosity and cracks that permeate the ceramic coating. These defects in the coating provide sites subject to severe crevice corrosion. For these reasons, it is desirable that the coating contain at least 2 percent tungsten or molybdenum to increase the alloy's sulfidation resistance.

In addition, it may be useful to limit iron and nickel to less than 5 percent, because each of these elements may tend to reduce sulfidation resistance. Maintaining these elements at levels as low as commercially practical may tend to improve the sulfidation resistance of the alloy. The alloy may contain up to 5 percent carbon to strengthen the clad layer. Carbon levels above five percent may tend to decrease the corrosion resistance of the alloy.

A typical composition of the metal, alloy or metal-alloy composite powder comprises, by weight percent, about 5 to 20 carbon, about 20 to 40 chromium, about 0 to 5 nickel, about 0 to 5 iron, about 0 to 25 molybdenum, about 0 to 25 tungsten, about 0 to 3 silicon, about 0 to 3 boron, and balance cobalt. Preferably, the metal, alloy or metal-alloy composite powder comprises, by weight percent, about 20 to about 90 cobalt-chromium-carbide; and balance an alloy component consisting essentially of, by weight percent, about 1 to about 25 tungsten, about 2 to about 12 nickel, 0 to about 7 copper, 0 to about 5 molybdenum, about 0.1 to about 1.5 manganese, 0 to about 1.5 niobium and tantalum, 0 to about 1.2 titanium, 0 to about 2.0 aluminum, and about 0.1 to about 2 silicon, with the balance iron (Fe).

Another illustrative metal, alloy or metal-alloy composite powder comprises, by weight percent, about 10 to 30 chromium, about 1 to 10 molybdenum, about 1 to 10 aluminum, about 1 to 10 iron, about 1 to 10 tantalum, about 0 to 5 manganese, about 0 to 5 titanium, about 0 to 5 carbon, about 0 to 3 boron, 0 to 3 zinc, and balance nickel.

Preferably, the metal, alloy or metal-alloy composite powder comprises, by Weight percent, about 20 to about 90 nickel-chromium-aluminum; and balance an alloy component consisting essentially of, by weight percent, about 1 to about 25 tungsten, about 2 to about 12 cobalt, 0 to about 7 copper, 0 to about 5 molybdenum, about 0.1 to about 1.5 manganese, 0 to about 1.5 niobium and tantalum, 0 to about 1.2 titanium, 0 to about 2.0 carbon, and about 0.1 to about 2 silicon, with the balance iron (Fe).

The cladding operation proceeds as the laser and powder feed traverse a face of the workpiece. A preferred linear velocity for the cladding process can be between about 5 to about 15 inches per minute. The power of the laser during the operation can be within the range of about 100 to about 500 watts. The laser cladding may be limited to the area on the workpiece that receives the heating effect of the laser. Thus, in a preferred embodiment, the clad area is within the range of about 0.001 to about 0.010 square inches (0.0064516 to 0.064516 square centimeters). Limiting the clad area reduces the likelihood of heat induced microcracks appearing in the workpiece as a result of the cladding operation. The thickness of the laser clad metal, alloy or metal-alloy composite on said substrate can range between about 0.001 inch and about 0.10 inch.

Cladding over an area in excess of the 0.001 to 0.010 square inch range may also be achieved. The cladding method of such a larger area comprises a series of separate laser cladding operations. Each individual cladding step comprises a laser cladding operation for an area of a workpiece within a range of about 0.001 to about 0.010 square inches. The cladding of such an area will achieve a successful laser fusion with the acceptable fusion of powder to workpiece. After an individual area has been clad, it is allowed to cool. Upon cooling, a second, neighboring area proximate to the first area can then receive a laser fusion operation. In this manner, individual laser fusion operations may be performed to achieve a laser fusion on an overall area of desired size.

While the laser cladding operation may be adapted to other kinds of workpieces, it is designed and intended for particular application to components used in high temperature-corrosive applications, such as those associated with metallurgical vessels' lances, nozzles and tuyeres, for extending their service life under such severe conditions.

It should be appreciated that the described method need not be performed in the order in which it is described, but that this description is merely exemplary of one method. A suitable workpiece is first identified. Inspection of the workpiece confirms that the workpiece is a suitable candidate for cladding. The workpiece should not suffer from mechanical defects or other damage that would disqualify it from operating high temperature-corrosive applications, such as those associated with metallurgical vessels' lances, nozzles and tuyeres. The workpiece may be subjected to pre-cladding operations to prepare the piece for cladding.

In an embodiment, the workpiece receives a grit blasting/polishing treatment Grit blasting/polishing removes materials that interfere with laser cladding such as corrosion, impurity buildups, and contamination from the face of the workpiece. Next a digital monitoring system of the controller verifies the clad path on the workpiece. Using digital imaging through a video camera, the controller records surface and dimensional data from the workpiece. The operator enters clad path parameters through the controller. Parameters such as clad path geometry or “stitching”, distances, and linear velocities are entered. Information regarding the cladding such as laser power and powder feed rates is also entered to effect superficial heating of the workpiece surface.

After these preparatory steps, laser cladding commences. A first deposition pass takes place. Then a series of material deposition steps are repeated, if necessary, through repetitious of steps. In the first pass, the laser cladding process deposits a layer of metal, alloy or metal-alloy composite powder onto the substrate surface. The thickness of such deposit is between about 20 to about 30 thousands of an inch. The rate of movement of the workpiece relative to the laser depends on the desired thickness of the deposit, but a range of rates of between about S to about 15 inches per minute can be used. Upon conclusion of a first cladding pass, the controller will check the thickness of the clad deposit, if the build-up of material is below that desired, a second cladding pass occurs. While a single cladding pass may be sufficient to deposit the desired thickness of material, it is also the case that multiple passes may be needed to achieve the desired dimension of newly deposited material. In this manner a series of cladding passes can build up a desired thickness of newly deposited metal, alloy or metal-alloy composite powder. When the digital viewer determines that the thickness of material has reached, the desired limit, cladding ceases.

The workpiece is then machined to return it to a desired configuration or dimension. The deposition of powdered metal, alloy or metal-alloy composite may result in an uneven surface. Machining restores an even surface of a desired dimension. Similarly, it may be desirable to overdeposit material in order to assure that no voids or low spots remain on the substrate surface. Known machining techniques may be used to remove excess cladding material.

Post cladding steps may also include procedures such as a heat treatment to achieve stress relief. Post-cladding treatment may include hardsurfacing/polishing with materials.

A primary advantage of the disclosed laser cladding method is the utilization of a laser beam comprised of wavelengths from about 300 to about 10,600 nanometers allowing superficial heating of the substrate surface. The use of such a laser allows sufficient heating of the substrate surface and powdered metal, alloy or metal-alloy composite in order to form a fusion bond between the substrate and metal, alloy or metal-alloy composite material. The heat, however, is superficial and so concentrated that the cracking and damage encountered in other cladding techniques is avoided. The degree of fusion and hardness of the clad between the substrate and new material is highly desirable for copper or similar materials used in high temperature-corrosive applications, such as those associated with metallurgical vessels' lances, nozzles and tuyeres, for extending their service life under such severe conditions. In all cases, during the entire spraying process, care must be taken to assure that the surface does not become overheated and cause distortion of the substrate. On small parts, to eliminate overheating, compressed air or a cooling gas may be used to blow on the part to facilitate cooling.

Another advantage of this method can be the small amount of powdered metal, alloy or metal-alloy composite consumed by the laser fusion operation. The lasers useful in this invention efficiently bind the powdered alloy to the substrate material with little waste of powder. This realizes a cost savings in material.

In the prior art, weld overlay on tuyeres are made with alloys with a similar melting temperature as copper, and they are relatively soft, providing little resistance to abrasion/erosion and sulfur dioxide (SO₂) attack. Using the laser cladding techniques of this invention, harder and higher melting temperature materials can be overlaid.

As discussed below, the clad overlay can be used as undercoat for thermal spray ceramic coatings in order to prevent spalling of the coating due to the SO₂ attack by crevice corrosion of the substrate. Lance tips and nozzles can be overlaid with SO₂ resistant alloys with or without a thermal spray ceramic coating. Caster molds can be clad with a heat resistant alloy which eliminates the spalling problem with the hard chrome plating due to cracking a the liquid meniscus and crevice corrosion of the copper at the exit end by dissolved mold flux in splashing cooling water. Mold flux is essentially a mixture of molten salts and oxides that attaches to the slab surface upon freezing in the mold.

In an embodiment, a ceramic zirconia-base layer can cover the laser clad underlayer. Advantageously, the zirconia-base layer is selected from the group consisting of zirconia, partially stabilized zirconia and fully stabilized zirconia. Most advantageously, this layer is a partially stabilized zirconia, such as calcia, ceria or other rare earth oxides, magnesia and yttria-stabilized zirconia. The most preferred stabilizer is yttria. In particular, the partially stabilized zirconia with yttria provides excellent resistant to heat and slag/metal adhesion.

The zirconia-base ceramic layer may advantageously have a density of at least about eighty percent to limit the corrosive effects of hot acidic gases upon the under layer. Most advantageously, this density is at least about ninety percent.

An optional top layer may cover the ceramic layer and comprises a heat and hot erosion resistant carbide or boride coating. The coating material may be any heat resistant chromium boride or carbide such as, CrB, Cr₃ C₂, Cr₇ C₃ or Cr₂₃ C₆. The coating may be a pure carbide/boride or in a heat resistant alloy matrix of cobalt or nickel-base superalloy.

The thickness of each layer can be varied depending on the application and service environment. Advantageously, each layer has a thickness between about 0.002 inch to 0.040 inch Plasma, HVOF, and detonation gun and Super D-Gun™ techniques are effective for the under coat and the optional top layer. But, since HVOF provides insufficient melting of zirconia-based powders, the zirconia-base ceramic coatings can only be applied with plasma, detonation gun, or Super D-Gun™ processes.

The zirconia-base coating is preferably deposited on clad surfaces of the injection device such as tuyeres, lances or nozzles by means of a thermal spray process using a detonation gun or a Super D-Gun™ device. The coating material particles are therefore heated to a high temperature and accelerated to a high velocity (Super D-Gun is a trademark of Praxair Surface Technologies, Inc.). Most advantageously, the particle velocity is greater than about 750 meters/second for detonation gun deposition and greater than about 1000 meters/second for Super D-Gun™ deposition. The increased particle velocity improves bonding or adherence of the coating to the injection device.

Although not preferred at this time, other thermal spray or related processes such as high velocity oxy-fuel, high velocity air fuel, and cold spray may be viable if they are capable of generating sufficient particle velocity and particle temperature. Furthermore, it is possible to substitute very high velocity (kinetic energy) for some particle heating (thermal energy) and still achieve the desired microstructural characteristics necessary for the coatings of the injection devices.

The total coating thickness is obtained by traversing the gun or other thermal spray device relative to the exposed surface of the coated device so that it generates a precise, predetermined pattern of overlapping agglomerations of particles. More specifically, when using a detonation gun or a Super D-Gun, each circular agglomeration of particles deposited on at least one clad surface of the injection device forms the coating portions of less than about 25 micrometers in thickness and about 15 mm to 35 mm in diameter.

The method forms a coating on a portion or all of clad surfaces of the lance, nozzle or tuyere. In particular, it relates to depositing a coating of predetermined thickness on the clad surface of a tuyere or other gas injection device. Preferably, the process uses a thermal spray device to coat the entire clad surface of the injection device.

The inherent flexibility of the laser cladding and optionally hardsurfacing processes can accommodate most variations in component geometry to obtain the desired size, shape and thickness of coating deposit. Single beads can be deposited in widths ranging from 0.060 inches to more than 2.000 inches, and clad deposits can be applied in incremental layers to any required thickness. For broad surface areas, parallel beads of clad deposit are applied with sufficient overlap, or tie-in, to ensure a uniform coating thickness. For flat or large radius surfaces the coating alloy is continuously fed ahead of the translating laser beam, but for non-horizontal or small radius surfaces the powder feed can be injected directly into the melt fusion zone using an injection nozzle with pressurized inert carrier gas. While laser cladding is a line-of-sight process, special optical configurations can be used to coat relatively inaccessible regions, such as the inside surfaces of hollow cylinders, to substantial depths.

Coatings applied by laser cladding and hardsurfacing processes are metallurgically superior to coatings applied using conventional electric-arc cladding processes such as gas-metal-arc (GMAW), submerged-arc (SAW) and transferred plasma-arc (PTA) principally due to reduced heat input and low dilution. Laser coatings exhibit superior mechanical properties (hardness, toughness, ductility, strength) and enhanced wear, corrosion and fatigue properties vital to components subjected to severe operating environments. Furthermore, the implementation of laser cladding techniques can provide alternate solutions to conventional coating methods such as chromium electroplating. The superiority of laser cladding or coating properties versus conventional claddings or coatings has been observed for applications involving cavitation-erosion, erosion by particulate impingement, hot corrosion, sliding wear and thermal (low-cycle) fatigue.

In an embodiment, a YAG-generated laser beam can be directed at the part surface to be coated, providing the energy necessary to melt and fuse the coating material to the copper substrate. Different types of YAG lasers can be used emitting light at wavelengths between approximately 700 and 1060 nanometers. The cladding material can be in-situ fed into a melt pool or pre-placed onto the substrate surface prior to laser processing. A clad can be produced by relative motion of the laser beam on the substrate surface. An inert shielding gas, e.g., helium or argon, can be employed to protect the melt pool from the surrounding atmosphere. The substrate to be coated may be heated prior to laser processing or during laser processing in order to reduce laser power requirements and to improve fusion between the substrate and the coating material. The clad substrate can undergo further processing such as polishing.

### EXAMPLE

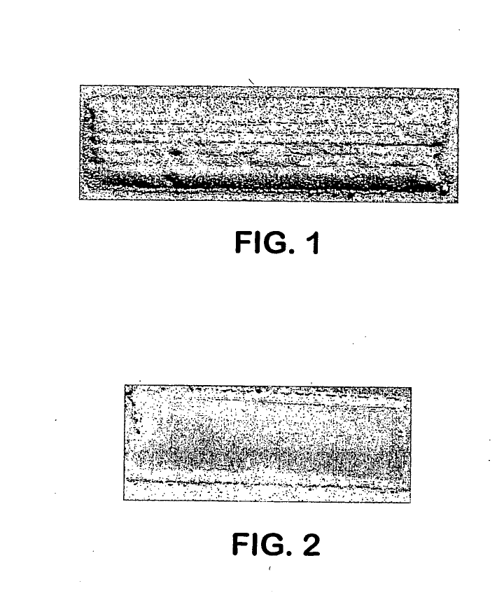

A laser cladding process was conducted utilizing Nd:YAG laser. The process parameters are set forth below. The coating material was injected into a melt pool. The laser beam was guided over the part surface generating a weld bead. Overlapping the individual weld bead at a certain index produced the clad. The clad layer was then polished. FIG. 1 shows a Nd:YAG laser clad surface of a CoCrC coating applied onto the copper substrate in accordance with this example. FIG. 2 shows a Nd:YAG laser clad and polished surface of a CoCrC coating applied onto the copper substrate in accordance with this example.

Base metal: Copper (Cu)
Coating material: CoCrC alloy
Laser: Nd:YAG, diode pumped, fiber delivered maximum output power of 5 kW
Laser power utilized: 4 kW
Laser spot size: approximately 3 mm diameter
Surface speed: 250-400 mm per minute

### Index: 1.5 mm

Powder feed rate: 6 grams per min.
Part temperature: 800° F.

Other variations of the disclosed method are within the intended scope of this invention as claimed below. As previously stated, detailed embodiments of the present invention are disclosed herein; however, it is to be understood that disclosed embodiments are merely exemplary of the invention that may be embodied in various forms.

1. A method for applying a high melting point material onto a substrate, said substrate having a melting point temperature below the melting point temperature of the high melting point material, comprising:
(a) moving a laser beam generated from a laser over the surface of said substrate, said laser beam comprised of wavelengths from about 300 to about 10,600 nanometers;
(b) providing a metal, alloy or metal-alloy composite powder to the surface of said substrate; and
(c) generating sufficient power to the laser to superficially heat said substrate and to effect a fusion bond between the metal, alloy or metal-alloy composite powder and the surface of said substrate.

2. The method of claim 1 wherein said laser beam is comprised of wavelengths of about 1060 nanometers or less.

3. The method of claim 1 wherein said laser beam is comprised of wavelengths from about 700 to about 1060 nanometers.

4. The method of claim 1 wherein said laser creates superficial heating of said substrate without distortion of said substrate.

5. The method of claim 1 wherein the step of providing said metal, alloy or metal-alloy composite powder comprises providing the powder through a powder discharge nozzle that has an axial alignment different from the axial alignment of the laser.

6. The method of claim 1 wherein steps (a), (b) and (c) are conducted in any order sufficient for applying said high melting point material onto said substrate.

7. The method of claim 1 wherein the metal, alloy or metal-alloy composite powder comprises a cobalt-based superalloy or a nickel-based superalloy.

8. The method of claim 1 wherein the metal, alloy or metal-alloy composite powder comprises, by weight percent, about 5 to 20 carbon, about 20 to 40 chromium, about 0 to 5 nickel, about 0 to 5 iron, about 0 to 25 molybdenum, about 0 to 25 tungsten, about 0 to 3 silicon, about 0 to 3 boron, and balance cobalt.

9. The method of claim 1 wherein the metal, alloy or metal-alloy composite powder comprises, by weight percent, about 10 to 30 chromium, about 1 to 10 molybdenum, about 1 to 10 aluminum, about 1 to 10 iron, about 1 to 10 tantalum, about 0 to 5 manganese, about 0 to 5 titanium, about 0 to 5 carbon, about 0 to 3 boron, 0 to 3 zinc, and balance nickel.

10. The method of claim 1 wherein said metal, alloy or metal-alloy composite powder is cobalt-chromium-carbide or nickel-chromium-aluminum.

11. The method of claim 1 wherein the thickness of the laser clad metal, alloy or metal-alloy composite on said substrate is between about 0.001 inch and about 0.10 inch.

12. The method of claim 1 wherein the substrate is copper or a copper-base alloy.

13. The method of claim 1 wherein said laser comprises a neodymium YAG laser or laser diode.

14. The method of claim 1 wherein said substrate comprises a machine component selected from tuyeres in a blast furnace, lance tips in a basic oxygen furnace, nozzles in an electric arc furnace, and mold plates in continuous slab casters.
